(19) United States
(12) Patent Application Publication
(10) Pub. No.: US 2022/0418101 A1
(43) Pub. Date: Dec. 29, 2022

(54) MULTI-LAYER CIRCUIT BOARD WITH EMBEDDED COMPONENTS AND METHOD FOR MANUFACTURING SAME

(71) Applicants: HongQiSheng Precision Electronics (QinHuangDao) Co.,Ltd., Qinhuangdao (CN); Avary Holding (Shenzhen) Co., Limited., Shenzhen (CN)

(72) Inventor: CHENG-JIA LI, Qinhuangdao (CN)

(21) Appl. No.: 17/781,024

(22) PCT Filed: Apr. 27, 2020
(86) PCT No.: PCT/CN2020/087172

§ 371 Date: May 30, 2022

(51) Int. Cl. H05K 1/02; H05K 1/09; H05K 1/18; H05K 3/46

(52) U.S. Cl. CPC H05K 1/0298; H05K 1/092; H05K 1/186; H05K 3/4679; H05K 2201/2027; H05K 2201/09536

(57) ABSTRACT

A multi-layer circuit board with embedded components (100) in multiple layers and miniaturized form, with embedded electronic elements in a higher element density and shorter voltage paths includes a circuit board (10) provided with a mounting groove (101), and a plurality of elements (20). The elements (20) are arranged in the mounting groove (101), and the circuit board (10) includes several vertically-stacked circuit substrates (11, 12, 13, 14) arranged around the mounting groove (101), The multi-layer circuit board with embedded components circuit board (100) includes a conductive member (30) arranged in the mounting groove (101) and electrically connecting the elements (20) and the layers of conductive circuits.

### FIELD

The subject matter herein relates to technical field of circuit board manufacture, especially relates to a multi-layer circuit board with embedded components and manufacturing method thereof.

### BACKGROUND

Modern circuit boards must have high density and high reliability. To improve the density of circuit board, achieve miniaturization, and improve the reliability of circuit boards, technology of embedding components boards is more and more favored by the industry. Embedded components not only reduce mounting areas of elements in circuit board, and achieve miniaturization of circuit board, but also shorten wiring lengths and reduce parasitic inductances, and improve product density and electrical performance of circuit board.

However, integrating more and more embedded components and allowing full functions of the embedded components is challenging.

### SUMMARY

In view of the above problem, the present disclosure provides a multi-layer circuit board with a plurality of embedded components, and elements can be directly connected with each other.

An embodiment of the present disclosure provides a multi-layer circuit board with embedded components, which includes a circuit board defined with a mounting groove and a plurality of elements. The elements are arranged in the mounting groove and electrically connected with the circuit board. The circuit board includes a plurality of circuit substrates arranged surround the mounting groove. The circuit substrates are stacked. The multi-layer circuit board with embedded components includes conductive members, the conductive members are arranged in the mounting groove and electrically connect the elements with the circuit substrates. At least two elements are electrically connected to each other through the conductive member. The mounting groove is filled with an insulating and heat-dissipating material. The insulating and heat-dissipating material covers the elements.

In the vertical stacking of the circuit substrates, the elements are arranged in the mounting groove layer by layer.

The circuit substrates include a laminated first circuit substrate and a laminated second circuit substrate. The first circuit substrate includes a first substrate layer, a first conductive circuit layer, and a second conductive circuit layer. The first conductive circuit layer and the second conductive circuit layer are formed on the upper and lower surfaces of the first substrate layer. The second circuit substrate includes a second substrate layer and a third conductive circuit layer formed thereon. The second substrate layer is arranged on the second conductive circuit layer, and the third conductive circuit layer is formed on a side of the second substrate layer away from the second conductive circuit layer.

The second conductive circuit layer also includes a mounting area, the second circuit substrate is arranged surround the mounting area to form the mounting groove. The mounting area includes a plurality of mounting portions on a bottom surface of the mounting groove. The third conductive circuit layer is exposed from side walls of the mounting groove.

The mounting portions carry conductive pastes. At least one element is arranged on the conductive paste and electrically connected with the second conductive circuit layer.

The circuit substrates further include a third circuit substrate arranged on the second circuit substrate. The third circuit substrate includes a third substrate layer and a fourth conductive circuit layer. The third substrate layer is arranged on the third conductive circuit layer. The fourth conductive circuit layer is formed on a side surface of the third substrate layer away from the third conductive circuit layer. The third circuit substrate is arranged surround the mounting groove, and the fourth conductive circuit layer is exposed from the side walls of the mounting groove. The plurality of elements are electrically connected to the fourth conductive circuit layer through the conductive members.

The present disclosure provides a method of manufacturing the multi-layer circuit board with embedded components as described in above embodiments. The manufacturing method includes following steps:

providing a circuit board with a plurality of circuit substrates, and forming a mounting groove on the circuit board;

installing a plurality of elements and conductive members into the mounting groove, the conductive members electrically connecting the elements with the circuit substrates;

infilling an insulating and heat-dissipating material into the mounting groove, the material covers the elements and the conductive members. The conductive members are formed of conductive glue;

the conductive members are between at least two elements to electrically connect the two elements.

Particularly, the step of “providing a circuit board with a plurality of circuit substrates, and forming a mounting groove on the circuit board” includes:

providing a first circuit substrate, the first circuit substrate includes a first substrate layer and first and second conductive circuit layers formed on the upper and lower surfaces of the first substrate layer, the second conductive circuit layer includes a mounting area;

providing a second circuit substrate arranged surround the mounting area to form the mounting groove. The second circuit substrate includes a second substrate layer and a third conductive circuit layer. The second substrate layer is arranged on the second conductive circuit layer, and the third conductive circuit layer is formed on the side surface of the second substrate layer away from the second conductive circuit layer.

The mounting area includes a plurality of mounting portions protruded on the bottom surface of the mounting groove, and the third conductive circuit layer is exposed from the side walls of the mounting groove. The step of “installing a plurality of elements and conductive members into the mounting groove” includes: laying the conductive paste on a top surface of the mounting portions, and positioning at least one element on the conductive paste to electrically connect the element with the second conductive circuit layer.

Particularly, before the step of “installing a plurality of elements and conductive members into the mounting groove”, the manufacturing method further provides a third circuit substrate, the third circuit substrate includes a third substrate layer and a fourth conductive circuit layer. The third substrate layer is arranged on the third conductive circuit layer, and the fourth conductive circuit layer is formed on the side surface of the third substrate layer away from the third conductive circuit layer. The third circuit substrate is arranged surround the mounting groove, the fourth conductive circuit layer is exposed from the side walls of the mounting groove, and each of the elements is electrically connected with the fourth conductive circuit layer from the side wall of the mounting groove, through the conductive member.

The stacked arrangement of circuit substrates in the multi-layer circuit board with embedded components allows a plurality of elements to be set in the mounting groove, the conductive members connect the plurality of elements with the plurality of conductive circuit layers, and the plurality of elements can be connected by the conductive members. The arrangement not only ensures full function of all the elements, but also reduces losses of the circuit.

### BRIEF DESCRIPTION OF THE DRAWINGS

FIG. 1 is a cross section view of a multi-layer circuit board with embedded components in an embodiment of the present disclosure.

FIG. 2 is a top schematic view of the multi-layer circuit board with embedded components in an embodiment.

FIG. 3 is a cross section view of a first copper plated substrate of the circuit board.

FIG. 4 is a cross section view of a first circuit substrate with a first conductive circuit layer and a second conductive circuit layer formed by the first copper plated substrate of FIG. 3.

FIG. 5 is a cross section view of a second circuit substrate with a third conductive layer added to the second conductive circuit layer of FIG. 4.

FIG. 6 is a cross section view of a third copper plated substrate added on a third conductive circuit layer of FIG. 5.

FIG. 7 is a cross section view of a fourth conductive circuit layer formed on the third copper plated substrate of FIG. 6.

FIG. 8 is a cross section view of a fourth circuit substrate added on the fourth conductive circuit layer of FIG. 7.

FIG. 9 is a cross section view of the circuit board of FIG. 8 with a covering layer.

FIG. 10 is a cross section view of the circuit board of FIG. 9 after a surface treatment process.

FIG. 11 is a cross section view of the circuit board of FIG. 10 with conductive paste in the mounting groove.

FIG. 12 is a cross section view of the circuit board of FIG. 11 with a first element positioned in the mounting groove.

FIG. 13 is a cross section view of the mounting groove of the circuit board of FIG. 12 filled with an insulating and heat-dissipating material, the first element being covered by the insulating and heat-dissipating material.

FIG. 14 is a cross section view of the circuit board of FIG. 13 with conductive members positioned in the mounting groove.

FIG. 15 is a cross section view of the circuit board of FIG. 14 with a second element positioned in the mounting groove, the second element being electrically connected to the conductive member.

FIG. 16 is a cross section view of the mounting groove of the circuit board of FIG. 15 filled with the insulating and heat-dissipating material, the second element and the conductive member being covered by the material.

FIG. 17 is a cross section view of the circuit board of FIG. 16 with a third element and the conductive member positioned in the mounting groove.

FIG. 18 is a cross section view of the mounting groove of the circuit board of FIG. 17 filled with the insulating and heat-dissipating material, the third element and the conductive member being covered by the material.

### DESCRIPTION OF MAIN ELEMENTS OR ELEMENTS

Multi-layer circuit board 100; Circuit board 10; Mounting groove 101; First circuit substrate 11; First copper plated substrate 110; First substrate layer 111; First conductive circuit layer 112; Second conductive circuit layer 113; Mounting area 114; Mounting portion 115; Second circuit substrate 12; Second substrate layer 121; Third conductive circuit layer 122; Third circuit substrate 13; Third copper plated substrate 130; Third substrate layer 131; Fourth conductive circuit layer 132; Fourth circuit substrate 14; Fourth substrate layer 141; Fifth conductive circuit layer 142; Adhesive layer 15; Covering layer 16; Connecting portion 17; Element 20; Pin 201; First element 21; Second element 22; Third element 23; Conductive member 30; Conductive paste 31; Insulating and heat-dissipating material 40.

### DETAILED DESCRIPTION

In order to make the above-mentioned objects, features, and advantages of the present disclosure more obvious, a description of specific embodiments of the present disclosure will be described with reference to the accompanying drawings. The present disclosure can be implemented in many ways different from those described herein, and those skilled in the art can make similar improvements without violating the contents of the present disclosure. Therefore, the present disclosure is not to be considered as limiting the scope of the embodiments to those described herein.

It should be noted that when an element is described as “fixed to” another element, the element can be directly on another element or there can be an intermediate element. When an element is considered to be “connected” to another element, the element can be directly connected to another element or there may be intermediate elements at the same time. When an element is considered to be “positioned on” another element, the element can be positioned directly on another element or there may be intermediate elements at the same time. The terms “vertical”, “horizontal”, “left”, “right” and similar expressions used in this paper are for illustrative purposes only.

Unless otherwise defined, all technical and scientific terms used herein have the same meaning as commonly understood by one skilled in the art. The terms used in the present disclosure herein are only for describing specific embodiments, and are not intended to limit the present disclosure.

The present disclosure provides a multi-layer circuit board with embedded components, the circuit board having a mounting groove and a plurality of electronic elements. The elements are arranged in the mounting groove and electrically connected with the circuit board. The circuit board includes a plurality of circuit substrates arranged surround the mounting groove, the circuit substrates are stacked vertically. The multi-layer circuit board with embedded components includes conductive members, which are arranged in the mounting groove and which electrically connect the plurality of elements with multiple layers of conductive circuits, and at least two parts are electrically connected to each other through the conductive member.

The stacked circuit substrates in the multi-layer circuit board with embedded components enable the plurality of elements to be set in the mounting groove, the conductive members connect the plurality of elements with the plurality of conductive circuit layers, and the plurality of elements can be connected by the conductive members.

Some embodiments of the present disclosure are described in detail. Without conflict, the following embodiments and features in the embodiments can be combined with each other.

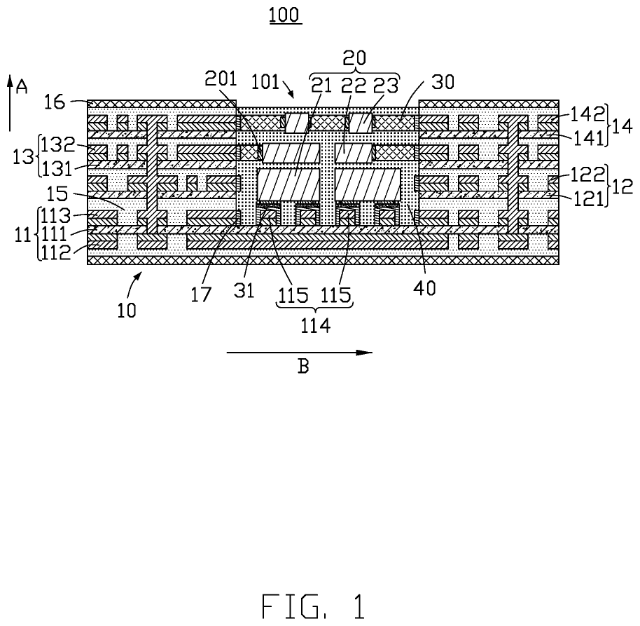

Referring to FIG. 1, in one embodiment, the multi-layer circuit board with embedded components 100 includes a circuit board 10 provided with a mounting groove 101 and a plurality of elements 20. The elements 20 are arranged in the mounting groove 101 and electrically connected to the circuit board 10. The circuit board 10 includes first to fourth circuit substrates 11-14 arranged surround the mounting groove 101, such circuit substrates being stacked vertically. The multi-layer circuit board with embedded components 100 further includes conductive members 30 arranged in the mounting groove 101 and electrically connecting the plurality of elements 20 with the plurality of circuit substrates. At least two elements 20 are electrically connected to each other through the conductive member 30.

In one embodiment of the present disclosure, an insulating and heat-dissipating material 40 is infilled in the mounting groove 101, and all the elements 20 are covered by the insulating heat dissipating material 40. The plurality of circuit substrates includes a first circuit substrate 11 and a second circuit substrate 12, the second circuit substrate 12 is vertically stacked on the first circuit substrate 11. The first circuit substrate 11 includes a first substrate layer 111, a first conductive circuit layer 112, and a second conductive circuit layer 113, the first and second conductive circuit layers 112 and 113 being formed on upper and lower surfaces of the first substrate layer 111. The second circuit substrate 12 includes a second substrate layer 121 and a third conductive circuit layer 122 formed on the second substrate layer 121. The second substrate layer 121 is arranged on the second conductive circuit layer 113, and the third conductive circuit layer 122 is formed on a side of the second substrate layer 121 away from the second conductive circuit layer 113. The elements 20 are arranged in the mounting groove 101 layer by layer. The circuit board 10 further includes an adhesive layer 15, the adhesive layer 15 is positioned between the first circuit substrate 11 and the second circuit substrate 12 to bond the first circuit substrate 11 and the second circuit substrate 12 together. The insulating and heat-dissipating material 40 can achieve a heat dissipation effect in three dimensions in the mounting groove 101, and dissipates heat of the circuit board 10 and elements 20, so as to improve quality and robustness of the circuit board 10. The infilling of the insulating and heat-dissipating material 40 removes air from the mounting groove 101, so that the insulating and heat-dissipating material 40 also serves to protect the elements 20 against impacts and vibration, and against ingress of moisture and other contaminants.

The plurality of circuit substrates further includes a third circuit substrate 13 and a fourth circuit substrate 14. The third circuit substrate 13 and the fourth circuit substrate 14 are arranged surround the mounting groove 101 and stacked on the second circuit substrate 12. The mounting groove 101 passes through the second circuit substrate 12, the third circuit substrate 13 and the fourth circuit substrate 14. The third circuit substrate 13 includes a third substrate layer 131 and a fourth conductive circuit layer 132 formed on the third substrate layer 131. The third substrate layer 131 is arranged on the third conductive circuit layer 122, and the fourth conductive circuit layer 132 is formed on a side surface of the third substrate layer 131 away from the third conductive circuit layer 122. The fourth circuit substrate 14 includes a fourth substrate layer 141 and a fifth conductive circuit layer 142 formed on the fourth substrate layer 141. The fourth substrate layer 141 is arranged on the fourth conductive circuit layer 132, and the fifth conductive circuit layer 142 is formed on a side surface of the fourth substrate layer 141 away from the fourth conductive circuit layer 132. The adhesive layer 15 is arranged between any adjacent circuit substrates and the upper and lower surfaces of the circuit board 10, to bond and fix the circuit substrates and protect the conductive circuit layers. In other embodiments, the circuit board 10 can include more circuit substrates according to actual needs, and the present disclosure is not limited to this.

Furthermore, the first substrate layer 111, each of the second substrate layer 121, the third substrate layer 131 and the fourth substrate layer 141 is defined with through holes, the through holes are coated with conductive materials. The first conductive circuit layer 112, the second conductive circuit layer 113, the third conductive circuit layer 122, the fourth conductive circuit layer 132, and the fifth conductive circuit layer 142 are electrically connected through the conductive coatings.

The second conductive circuit layer 113 includes a mounting area 114, and the second circuit substrate 12 is arranged surround the mounting area 114 to form the mounting groove 101. The mounting area 114 includes a plurality of mounting portions 115 protruding from a bottom surface of the mounting groove 101, and the third conductive circuit layer 122 is exposed from side walls of the mounting groove 101. The circuit board 10 further includes conductive paste 31, conductive paste 31 is arranged on the mounting portions 115. At least one element 20 is arranged on the conductive paste 31 and electrically connected with the second conductive circuit layer 113. The fourth conductive circuit layer 132 and the fifth conductive circuit layer 142 are also exposed from the side walls of the mounting groove 101, and the plurality of elements 20 are electrically connected with the fourth conductive circuit layer 132 and the fifth conductive circuit layer 142 through the conductive members 30.

Specifically, the plurality of elements 20 includes a first element 21, a second element 22 and a third element 23. In an embodiment of the present disclosure, the plurality of elements 20 are provided with pins 201. The first element 21 is arranged on the conductive paste 31, the pins 201 of the first element 21 are located on a bottom of the first element 21 and connected to the conductive paste 31. The first element 21 is connected to the second conductive circuit layer 113 along a first direction (the direction indicated by arrow A in FIG. 1). The second element 22 is positioned above the first element 21 and aligned with the fourth conductive circuit layer 132. Pins 201 of the second element 22 are arranged on sides of the second element 22. The conductive member 30 can be a conductive adhesive, which is arranged between the fourth conductive circuit layer 132 and the sides of the second element 22. Pins 201 on the side of the second element 22 are connected to the conductive member 30, and the second element 22 is electrically connected to the fourth conductive circuit layer 132 along a second direction (the direction indicated by arrow B in FIG. 1). The third element 23 is positioned above the second element 22 and aligned with the fifth conductive circuit layer 142. A conductive member 30 is also arranged between sides of the third element 23 and the fifth conductive circuit layer 142. Pins 201 of the third element 23 are connected to the conductive member 30 to electrically connect with the fifth conductive circuit layer 142. Furthermore, a conductive member 30 is also arranged between the adjacent third elements 23, and the adjacent pins 201 of the two third elements 23 are electrically connected to the conductive part 30, to achieve a direct connection between the elements without passing through the circuit board, giving full play to the function of the elements and reducing the losses of circuit. In other embodiments, a plurality of elements 20 arranged in the mounting groove 101 can electrically connect to the third conductive circuit layer 122, or to other elements, etc. in the same way, the present application is not limited.

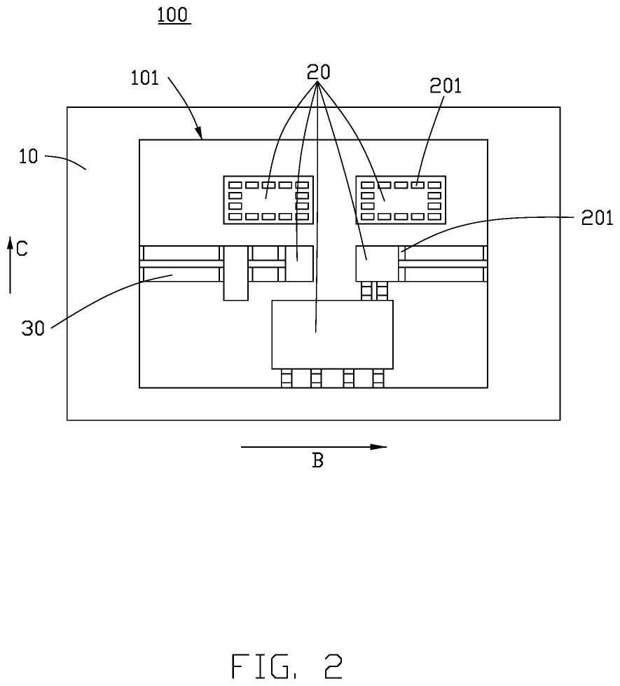

Referring to FIG. 2, in an embodiment, in a top layer or other layer of the circuit board 10, a plurality of elements 20 can also be set successively along a third direction (the direction indicated by arrow C in FIG. 2). The plurality of elements 20 arranged in the mounting groove 101 can be connected to the circuit board 10 in the third or second direction through the conductive member 30. Adjacent elements 20 can also be connected in the third or second direction through the conductive member 30, so as to achieve direct connection between elements. Furthermore, top and/or bottom surfaces of the elements 20 can also be provided with pins 201, so that the elements 20 are connected to the circuit board 10 in the first direction.

Referring to FIG. 1 and FIG. 2, the stacked arrangement of circuit substrates increases a volume of mounting groove 101. The plurality of elements 20 can connect to the circuit board 10 in multiple three-dimensional directions of the mounting groove 101, make better use of the internal space of mounting groove 101. Any two elements 20 can also be directly connected through the conductive members 30, which can improve the integration of the circuit board 10 and improve the space utilization in the circuit board 10.

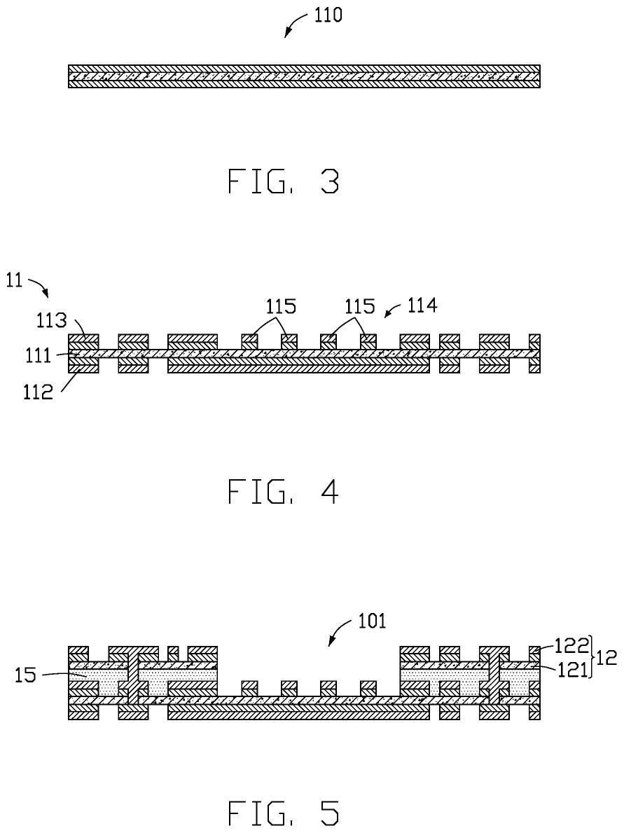

Referring to FIGS. 3 to 18, an embodiment of the present disclosure also provides a manufacturing method of the multi-layer circuit board with embedded components 100. The manufacturing method includes following steps:

providing a circuit board 10 having a plurality of circuit substrates, and forming a mounting groove 101 on the circuit board 10;

installing a plurality of elements 20 and conductive members 30 into the mounting groove 101, the conductive members 30 electrically connecting the plurality of elements 20 with the plurality of circuit substrates;

the conductive member 30 is arranged between at least two elements 20 to electrically connect the two elements 20.

The plurality of circuit substrates includes a first circuit substrate 11, a second circuit substrate 12, a third circuit substrate 13, and a fourth circuit substrate 14. Specifically, referring to FIG. 3 and FIG. 4, an embodiment of the present disclosure provides a first copper plated substrate 110, the first copper plated substrate 110 includes a first substrate layer 111. First and second conductive circuit layers 112 and 113 are respectively formed on lower and upper surfaces of the first copper plated substrate 110, that is, the first conductive circuit layer 112 and the second conductive circuit layer 113 are respectively formed on the upper and lower surfaces of the first substrate layer 111, to complete the step of providing the first circuit substrate 11. The mounting area 114 is formed in substantially a middle area of the second conductive circuit layer 113. The mounting area 114 includes a plurality of mounting portions 115.

Referring to FIG. 5, an adhesive layer 15 and a second circuit substrate 12 are successively arranged surround the mounting area 114 on the second conductive circuit layer 113 to form the mounting groove 101. The second circuit substrate 12 includes a second substrate layer 121 and a third conductive circuit layer 122. The second substrate layer 121 is arranged on the adhesive layer 15, and the third conductive circuit layer 122 is formed on the side surface of the second substrate layer 121 away from the second conductive circuit layer 113. The mounting area 114 is located at the bottom of the mounting groove 101, the mounting portion 115 is on the bottom surface of the mounting groove 101, and the third conductive circuit layer 122 is exposed from the side walls of the mounting groove 101. Each of the first substrate layer 111 and the second substrate layer 121 is defined with through holes which are coated with conductive material . The first conductive circuit layer 112, the second conductive circuit layer 113, and the third conductive circuit layer 122 are electrically connected through the conductive coatings.

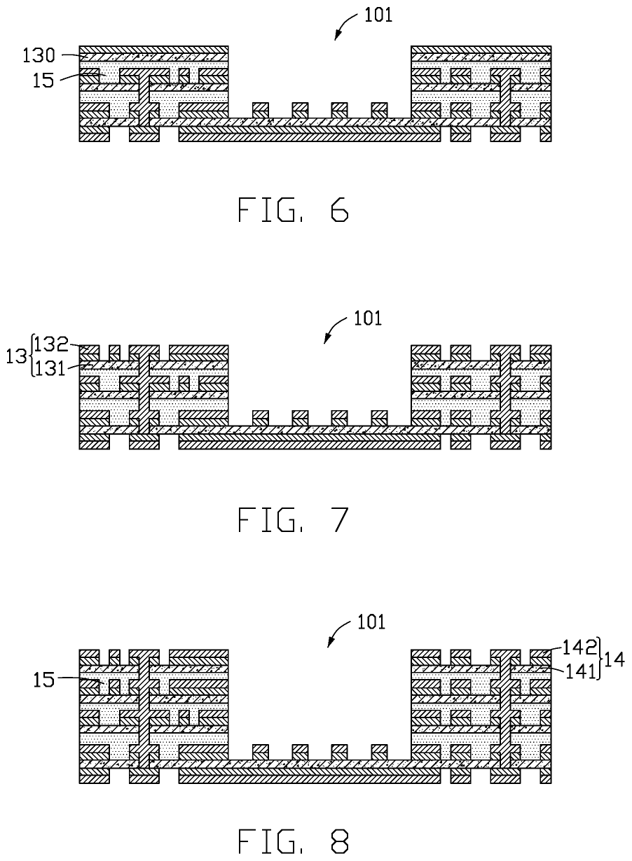

Referring to FIG. 6 and FIG.7, an adhesive layer 15 and a third copper plated substrate 130 are further added on the third conductive circuit layer 122 to provide a third circuit substrate 13. The third copper plated substrate 130 includes a third substrate layer 131, and a fourth conductive circuit layer 132 is formed on a side of the third substrate layer 131 away from the third conductive circuit layer 122, thereby the third circuit substrate 13 is formed. The adhesive layer 15 and the third circuit substrate 13 are arranged surround the mounting groove 101 to provide additional depth of the mounting groove 101. The fourth conductive circuit layer 132 is exposed from the side walls of the mounting groove 101, and the plurality of elements 20 can be electrically connected to the fourth conductive circuit layer 132 from the side walls of the mounting groove 101 through the conductive members 30.

Referring to FIG. 8, an adhesive layer 15 and a fourth circuit substrate 14 are successively added on the fourth conductive circuit layer 132 in the same way. The fourth circuit substrate 14 is arranged surround the mounting groove 101 to further increase the depth and accommodation volume of the mounting groove 101. The fourth circuit substrate 14 includes a fourth substrate layer 141 and a fifth conductive circuit layer 142. The fifth conductive circuit layer 142 is formed on a side surface of the fourth substrate layer 141 away from the fourth conductive circuit layer 132, and the fifth conductive circuit layer 142 is exposed from the side walls of the mounting groove 101. The third substrate layer 131 and the fourth substrate layer 141 are also defined with conductively-coated through holes. The first conductive circuit layer 112, the second conductive circuit layer 113, the third conductive circuit layer 122, the fourth conductive circuit layer 132, and the fifth conductive circuit layer 142 are thereby electrically connected to each other.

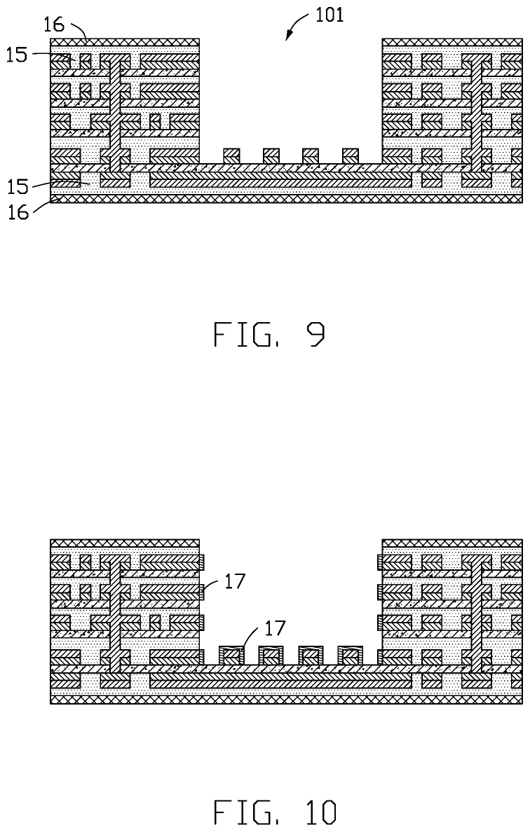

Referring to FIG. 9 and FIG. 10, a covering layer 16 is in place on the upper and lower surfaces of the circuit board 10 for protecting the circuit board 10. Whilst the covering layer 16 on the upper surface of the circuit board 10 is arranged surround the mounting groove 101, the mounting groove 101 is not thereby shielded or rendered inaccessible. Then, a surface treatment process is applied on the circuit board 10, and connecting portions 17 are added to parts where each conductive circuit layer exposes the mounting groove 101 for electrically connecting the plurality of elements 20.

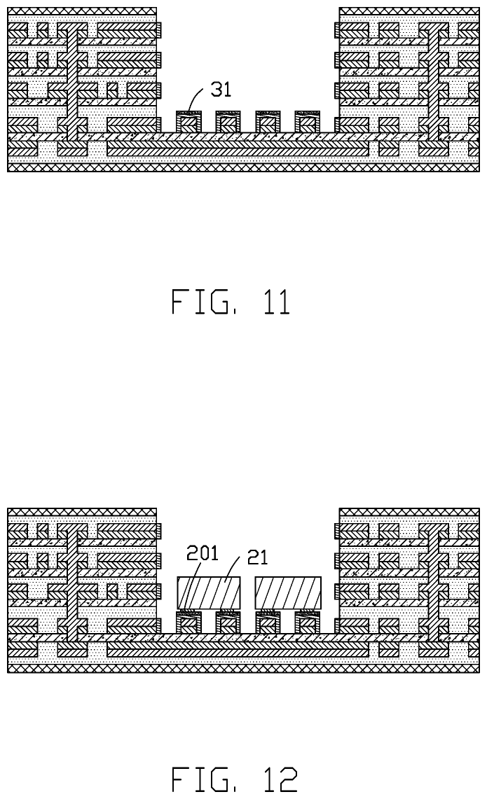

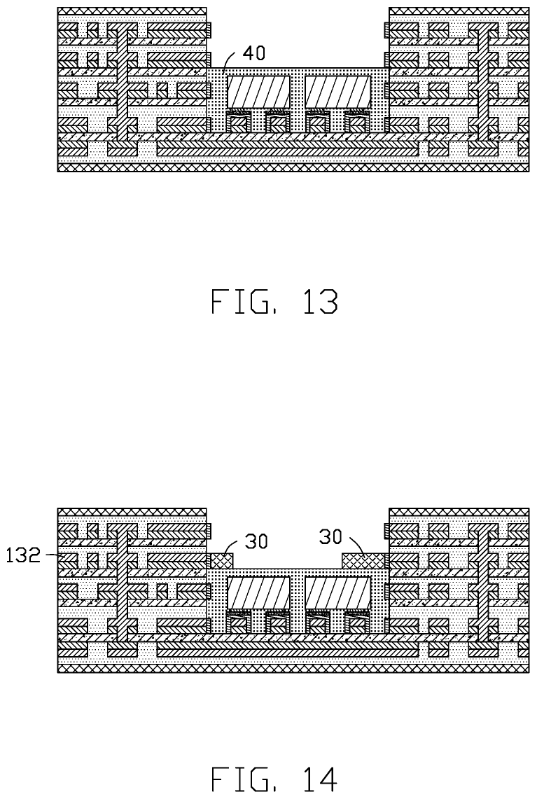

Referring to FIG. 11 and FIG. 12. after the surface treatment process is completed, the conductive paste 31 is further laid on the top surface of the mounting portion 115, and at least one element is positioned on the conductive paste 31 to electrically connect the at least one element with the second conductive circuit layer 113. The at least one element can be the first element 21, that is, after positioning the conductive paste 31, the first element 21 is installed on the conductive paste 31 and connected to the second conductive circuit layer 113 along the first direction. Referring to FIG. 13, after the first element 21 is installed, a first layer of insulating and heat-dissipating material 40 is filled in the mounting groove 101, the first element 21 is thereby embedded and secured.

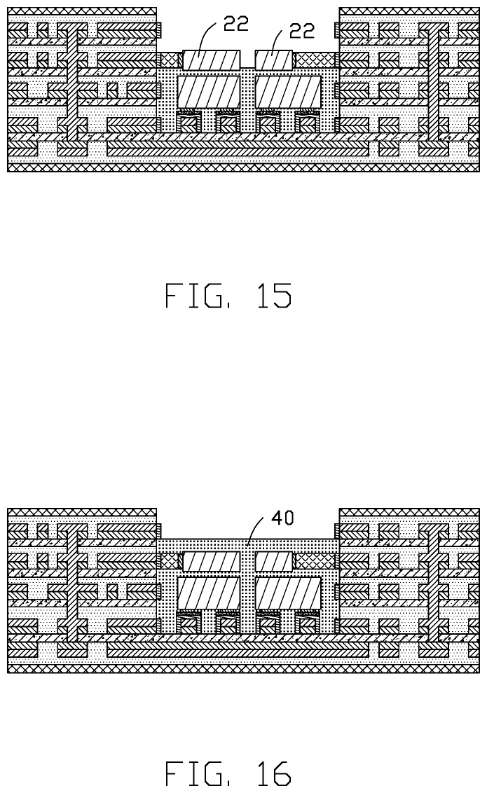

Referring to FIG. 14 and FIG. 15, after the first layer of insulating and heat-dissipating material 40 is applied, a conductive member 30 connecting the fourth conductive circuit layer 132 is positioned above the first layer of insulating and heat-dissipating material 40. Then a second element 22 connecting to the conductive member 30 is positioned in the mounting groove 101. The second element 22 connects to the fourth conductive circuit layer 132 from the side walls of the mounting groove 101 through the conductive member 30, that is, the second element 22 connects to the fourth conductive circuit layer 132 along the second direction. Referring to FIG. 16, after the installation of the second element 22 and the conductive member 30, a second layer of insulating and heat-dissipating material 40 is applied in the mounting groove 101, and the second layer of insulating and heat-dissipating material 40 covers the second element 22 and the conductive member 30.

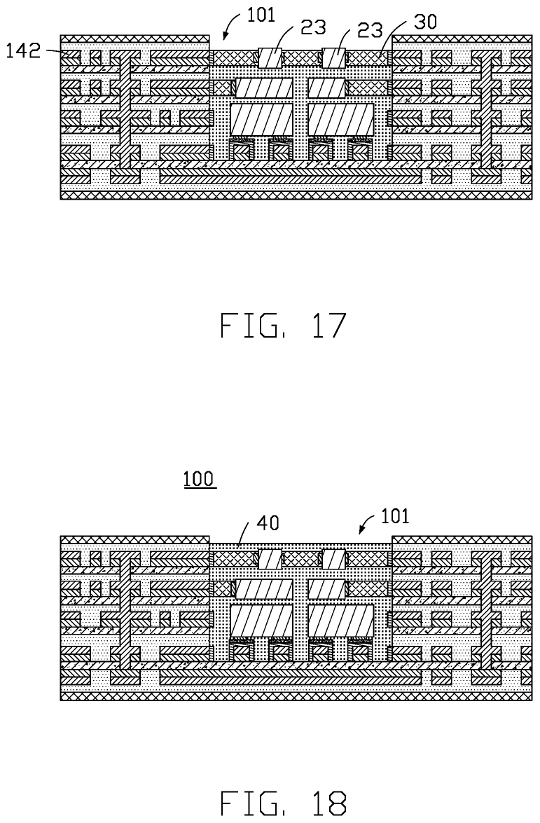

Referring to FIG. 17 and FIG. 18, after the second layer of insulating and heat-dissipating material 40 is applied, a third element 23 and a conductive member 30 are arranged above the second layer of insulating and heat-dissipating material 40. The third element 23 is electrically connected with the fifth conductive circuit layer 142 from the side walls of the mounting groove 101 through the conductive member 30, and adjacent third elements 23 are also directly connected to each other through the conductive member 30. After installing the third element 23 and the conductive member 30, a third layer of insulating and heat-dissipating material 40 is applied in the mounting groove 101. The third element 23 and the conductive member 30 are covered by the third layer of insulating and heat-dissipating material 40 to complete the manufacturing of the multi-layer circuit board with embedded components 100. The insulating and heat-dissipating material 40 covers a plurality of elements 20 and the conductive member 30 in the mounting groove 101.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

1. A multi-layer circuit board, comprising:
a circuit board defined with a mounting groove, the circuit board comprise a plurality of circuit substrates positioned surround the mount groove, and the plurality of circuit substrates are stacked;
a plurality of elements, positioned in the mounting groove, and the plurality of elements is electrically connected to the circuit board;
conductive members, positioned in the mounting groove, and electrically connected to the plurality of elements and the plurality of circuit substrate, the conductive member electrically connecting at least two of the plurality of elements.

2. The multi-layer circuit board of claim 1, wherein, the plurality of elements are arranged in the mounting groove layer by layer.

3. The multi-layer circuit board of claim 1, wherein the plurality of circuit substrates comprises a first circuit substrate and a second circuit substrate, the first circuit substrate and the second circuit substrate are stacked, the first circuit substrate comprise a first substrate layer, a first conductive circuit layer and a second conductive circuit layer are formed on upper and lower surfaces of the first substrate layer, the second circuit substrate comprises a second substrate layer and a third conductive circuit layer formed on the second substrate layer, the second substrate layer is arranged on the second conductive circuit layer, and the third conductive circuit layer is formed on a side of the second substrate layer away from the second conductive circuit layer.

4. The multi-layer circuit board of claim 3, wherein the second conductive circuit layer comprises a mounting area, the second circuit substrate is arranged surround the mounting area to form the mounting groove, the mounting area comprises a plurality of mounting portions protruding on a bottom surface of the mounting groove, the third conductive circuit layer is exposed from side walls of the mounting groove.

5. The multi-layer circuit board of claim 4, wherein conductive pastes are positioned on the mounting portions, at least one element is arranged on the conductive pastes and electrically connected with the second conductive circuit layer.

6. The multi-layer circuit board of claim 3, wherein the plurality of circuit substrates further comprises a third circuit substrate arranged on the second circuit substrate, the third circuit substrate comprises a third substrate layer and a fourth conductive circuit layer, the third substrate layer is arranged on the third conductive circuit layer, the fourth conductive circuit layer is formed on a side surface of the third substrate layer away from the third conductive circuit layer, the third circuit substrate is arranged surround the mounting groove, the fourth conductive circuit layer is exposed from the side walls of the mounting groove, the plurality of elements are electrically connected to the fourth conductive circuit layer through the conductive members.

7. A method of manufacturing a multi-layer circuit board, the manufacturing method comprising:
providing a circuit board with a plurality of circuit substrates, and forming a mounting groove on the circuit board;
installing a plurality of elements and conductive members into the mounting groove, the conductive members electrically connecting the plurality of elements with the plurality of circuit substrates, wherein the conductive members are made of conductive glue, and the conductive members are arranged between at least two of the plurality of elements to electrically connect the two elements;
infilling an insulating and heat-dissipating material into the mounting groove to, cover the plurality of elements and the conductive member.

8. The method of manufacturing the multi-layer circuit board of claim 7, wherein, providing a circuit board with a plurality of circuit substrates, and forming a mounting groove on the circuit board comprises:
providing a first circuit substrate, wherein the first circuit substrate comprises a first substrate layer and first and second conductive circuit layer formed on the upper and lower surfaces of the first substrate layer, the second conductive circuit layer defines a mounting area;
providing a second circuit substrate arranged surround the mounting area to form the mounting groove, wherein the second circuit substrate comprises a second substrate layer and a third conductive circuit layer, the second substrate layer is arranged on the second conductive circuit layer, and the third conductive circuit layer is formed on the side surface of the second substrate layer away from the second conductive circuit layer.

9. The method of manufacturing the multi-layer circuit board of claim 8, wherein, the mounting area comprises a plurality of mounting portions protruding on the bottom surface of the mounting groove, and the third conductive circuit layer is exposed from the side walls of the mounting groove; and
installing a plurality of elements and conductive members into the mounting groove comprises:
laying the conductive pastes on a top surface of the mounting portions, and positioning at least one element on the conductive paste to electrically connect each of plurality of elements with the second conductive circuit layer.

10. The method of manufacturing the multi-layer circuit board of claim 8, wherein, before installing a plurality of elements and conductive members into the mounting groove, the manufacturing method further comprises:
providing a third circuit substrate, the third circuit substrate comprises a third substrate layer and a fourth conductive circuit layer, the third substrate layer is arranged on the third conductive circuit layer, and the fourth conductive circuit layer is formed on the side surface of the third substrate layer away from the third conductive circuit layer, the third circuit substrate is arranged surround the mounting groove, the fourth conductive circuit layer is exposed from the side walls of the mounting groove, and the plurality of elements are electrically connected with the fourth conductive circuit layer from the side wall of the mounting groove, through the conductive member.

11. The method of manufacturing the multi-layer circuit board of claim 10, wherein, the manufacturing method further comprises:
providing a fourth circuit substrate, wherein the fourth circuit substrate comprises a fourth substrate layer and a fifth conductive circuit layer formed on the fourth substrate layer, the fourth substrate layer is arranged on the fourth conductive circuit layer, the fifth conductive circuit layer is formed on a side surface of the fourth substrate layer away from the fourth conductive circuit layer, the fifth conductive circuit layer is exposed from the side walls of the mounting groove, and the plurality of elements are electrically connected with the fifth conductive circuit layer from the side walls of the mounting groove, through the conductive member.

12. The method of manufacturing the multi-layer circuit board of claim 11, wherein, the manufacturing method further comprises:
applying a surface treatment process on the circuit board to add connecting portions to where each conductive circuit layer exposes the mounting groove for electrically connecting the plurality of elements.

13. The method of manufacturing the multi-layer circuit board of claim 7, wherein providing a circuit board with a plurality of circuit substrates, and forming a mounting groove on the circuit board comprises:
laying adhesive layer between any adjacent circuit substrates and upper and lower surfaces of the circuit board.

14. The method of manufacturing the multi-layer circuit board of claim 13, wherein the covering layer on the upper surface of the circuit board is arranged surround the mounting groove.

15. The multi-layer circuit board of claim 6, wherein the plurality of circuit substrates further comprises a fourth circuit substrate arranged on the third circuit substrate, the fourth circuit substrate comprise a fourth substrate layer and a fifth conductive circuit layer formed on the fourth substrate layer, the fourth substrate layer is arranged on the fourth conductive circuit layer, and the fifth conductive circuit layer is formed on a side surface of the fourth substrate layer away from the fourth conductive circuit layer.

16. The multi-layer circuit board of claim 15, wherein each of the second substrate layer, the third substrate layer and the fourth substrate layer is defined with through holes, the through holes are coated with a conductive material.

17. The multi-layer circuit board of claim 1, wherein the multi-layer circuit board further comprises a covering layer, the covering layer is placed on upper and lower surfaces of the circuit board.

18. The multi-layer circuit board of claim 17, wherein the covering layer on the upper surface of the circuit board is arranged surround the mounting groove.

19. The multi-layer circuit board of claim 17, wherein the multi-layer circuit board further comprises connecting portions, the connecting portions are positioned where each conductive circuit layer exposes the mounting groove.

20. The multi-layer circuit board of claim 1, wherein the multi-layer circuit board further comprises adhesive layers, the adhesive layers are arranged between any adjacent ones of the plurality of circuit substrates, and arranged on upper and lower surfaces of the circuit board.
